(19) United States
(12) Patent Application Publication
(10) Pub. No.: US 2024/0407174 A1
(43) Pub. Date: Dec. 5, 2024

(54) SEMICONDUCTOR DEVICES AND FABRICATION METHODS THEREOF AND MEMORY SYSTEMS

(71) Applicant: Yangtze Memory Technologies Co., Ltd., Wuhan (CN)

(72) Inventors: Tao Yang, Wuhan (CN); DongXue Zhao, Wuhan (CN); Changzhi Sun, Wuhan (CN); Wenxi Zhou, Wuhan (CN); ZhiLiang Xia, Wuhan (CN); ZongLiang Huo, Wuhan (CN)

(21) Appl. No.: 18/474,872

(22) Filed: Sep. 26, 2023

Related U.S. Application Data
(63) Continuation of application No. PCT/CN2023/097280, filed on May 30, 2023.

(51) Int. Cl. H10B 53/20; G11C 5/06; G11C 11/22; H01L 29/66; H01L 29/78; H10B 51/10; H10B 51/20; H10B 53/10

(52) U.S. Cl. CPC H10B 53/20; G11C 5/063; G11C 11/221; G11C 11/2273; G11C 11/2275; H01L 29/6684; H01L 29/78391; H10B 51/10; H10B 51/20; H10B 53/10

(57) ABSTRACT

The present application provides a semiconductor device and a fabrication method thereof, and a memory system. The semiconductor structure includes a first semiconductor structure which includes: a first select transistor including a first channel layer; a second select transistor including a gate; and a capacitor structure including a first electrode layer, wherein two ends of the first electrode layer are connected with the gate of the second select transistor and the first channel layer of the first select transistor respectively. The present application can avoid the problem of state destruction caused by reading operation.

### CROSS REFERENCE TO RELATED APPLICATION

This application is a continuation of International Patent Application PCT/CN2023/097280, filed on May 30, 2023, which is hereby incorporated by reference in its entirety.

### TECHNICAL FIELD

The present application relates to the technical field of semiconductor devices, and particularly to semiconductor devices and fabrication methods thereof, and memory systems.

### BACKGROUND

A transistor in a Ferroelectric Radom Access Memory (FeRAM) of a One Transistor One Capacitor (1T1C) or 1TXC (X is an integer greater than 1) architecture has both reading and writing functions.

### BRIEF DESCRIPTION OF THE DRAWINGS

In order to illustrate the technical solutions in some examples of the present application more clearly, the drawings to be used in the description of the examples will be briefly introduced below. Apparently, the drawings described below are only some examples of the present application. Those skilled in the art may also obtain other drawings according to these drawings without creative work.

FIG. 1A is a schematic circuit diagram of a semiconductor device provided by the present application.

FIG. 1B is a schematic circuit structure diagram of another semiconductor device provided by the present application.

FIG. 2A is a cross-sectional view of the semiconductor device as shown in FIG. 1B.

FIG. 2B is a top view of bit lines of the semiconductor device as shown in FIG. 2A.

FIG. 2C is a schematic diagram of a “0” state and a “1” state of a first select transistor and a second select transistor of the semiconductor device as shown in FIG. 2A.

FIG. 3 is a diagram of film layers of a circuit structure of the semiconductor device as shown in FIG. 1B.

FIG. 4 is a cross-sectional view of another semiconductor device provided by the present application.

FIG. 5 is a schematic diagram of a position relationship between third channel structures and first spacers of the semiconductor device as shown in FIG. 4.

FIG. 6 is a schematic diagram of a position relationship between second channel structures and second spacers of the semiconductor device as shown in FIG. 4.

FIG. 7 is a cross-sectional view of yet another semiconductor device provided by the present application.

FIG. 8 is a flowchart of a fabrication method of a semiconductor device provided by the present application.

FIG. 9 is a flowchart of forming a first stack structure in S1 as shown in FIG. 8.

FIG. 10 is a flowchart of forming a second stack structure in S2 as shown in FIG. 8.

FIG. 11 is a flowchart of forming a third stack structure in S2.

FIG. 12 is a cross-sectional view of a substrate with stack layers provided by the present application.

FIG. 13 is a cross-sectional view after forming first channel holes in the stack layers as shown in FIG. 12.

FIG. 14 is a top view of the first channel holes as shown in FIG. 13.

FIG. 15 is a cross-sectional view after forming first channel structures in the first channel holes as shown in FIG. 13.

FIG. 16 is an enlarged view of the first channel structure as shown in FIG. 15.

FIG. 17 is a cross-sectional view after forming spacing holes in the stack layers as shown in FIG. 15.

FIG. 18 is a top view of the spacing holes and the first channel structures as shown in FIG. 17.

FIG. 19 is a cross-sectional view after forming spacing structures in the spacing holes as shown in FIG. 17 to obtain a first stack structure.

FIG. 20 is a cross-sectional view after forming a word line at an end of the first stack structure away from the substrate as shown in FIG. 19.

FIG. 21 is a cross-sectional view after forming second channel holes penetrating through the word line in the first stack structure with the word line as shown in FIG. 20.

FIG. 22 is a top view of the second channel holes as shown in FIG. 21.

FIG. 23 is a cross-sectional view after forming second channel structures in the second channel holes as shown in FIG. 21.

FIG. 24 is an enlarged view of the second channel structure and the first channel structure as shown in FIG. 23.

FIG. 25 is a cross-sectional view after forming first bit lines on sides of the second channel structures away from the first stack structure as shown in FIG. 23 to obtain a second stack structure.

FIG. 26 is a top view of the first bit lines as shown in FIG. 25.

FIG. 27 is a cross-sectional view after forming a second semiconductor structure on a side of the second stack structure away from the first stack structure as shown in FIG. 25.

FIG. 28 is a cross-sectional view after removing the substrate in FIG. 27.

FIG. 29 is a cross-sectional view after forming a source line on a side of the first stack structure away from the second stack structure as shown in FIG. 28 and forming third channel structures penetrating through the source line.

FIG. 30 is a schematic diagram of modules of a memory system provided by the present application.

### DETAILED DESCRIPTION

The technical solutions in some examples of the present application will be described below clearly and completely in conjunction with the drawings in some examples of the present application. Apparently, the examples described are only part of, but not all of, the examples of the present application. All other examples obtained by those skilled in the art based on the examples in the present application without creative work shall fall in the scope of protection of the present application.

In the description of the present application, it is to be understood that the terms “upper”, “lower”, etc. indicate orientations or position relationships that are based on the orientations or position relationships as shown in the drawings, which are only intended to facilitate description of the present application and to simplify the description, instead of indicating or implying that the device or element indicated must have a specific orientation and be configured and operated in a specific orientation, and thus cannot be understood as limiting the present application. Furthermore, the terms “first” and “second” are only for the purpose of description and cannot be construed as indicating or implying relative importance or implicitly indicating the number of indicated technical features. Thus, features defined by “first” and “second” may explicitly or implicitly include one or more of the features. In the description of the present application, “a plurality of” means two or more, unless otherwise defined specifically.

In the description of the present application, it should be understood that the term “substrate” refers to a material onto which subsequent material layers are added. The substrate itself can be patterned. Materials added on top of the substrate can be patterned or can remain without a pattern.

In the description of the present application, it should be understood that the term “layer” refers to a material portion including a region with a thickness. A layer may extend over the entirety of an underlying or overlying structure or may have an extent less than the extent of the underlying or overlying structure. Furthermore, a layer may be a region of a homogeneous or inhomogeneous continuous structure that has a thickness less than the thickness of a continuous structure. A layer may extend horizontally, vertically, and/or along an inclined surface. A layer may include multiple sub-layers. For example, an interconnection layer may comprise one or more conductors and contact sub-layers in which interconnection lines and/or via contacts are formed, and one or more dielectric sub-layers.

The present application may repeat the reference numbers and/or reference letters in different implementations, and such repetitions are for the purposes of simplification and clarity. and do not indicate in themselves the relationships between various examples and/or settings as discussed.

In the FeRAM, a writing-back operation is required after the reading operation, but the reading operation is destructive, which will destroy the state of the FeRAM.

The present application aims at the technical problem that a select transistor in a ferroelectric memory of a 1TIC or 1TXC (X is an integer greater than 1) architecture needs a writing-back operation after a reading operation while the reading operation is destructive and will destroy the state of a FeRAM. In the present application, a first select transistor and a second select transistor are connected to a capacitor structure individually, and two ends of a first electrode layer of the capacitor structure are connected with a first channel layer of the first select transistor and a gate of the second select transistor respectively, such that the first select transistor and the second select transistor perform a writing operation and a reading operation respectively. As such, the second select transistor of the semiconductor device provided by the present application does not need the writing-back operation and a non-destructive reading operation can be achieved, which can effectively avoid the problem of state destruction caused by the reading operation.

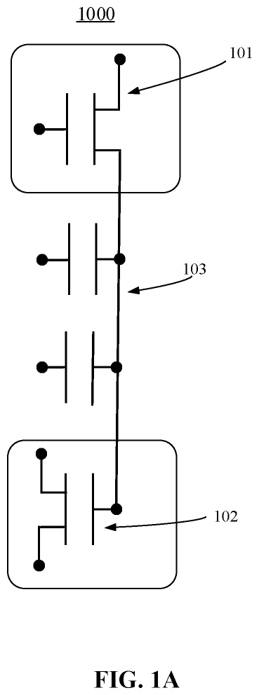

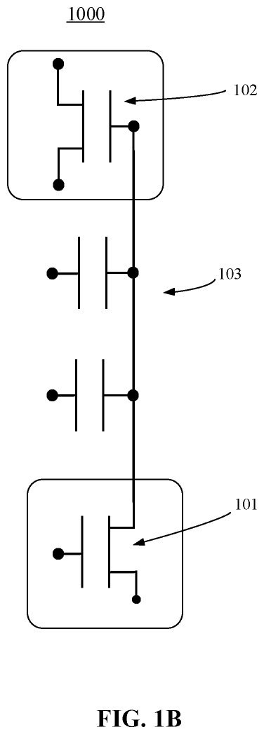

Referring to FIGS. 1A, 1B, 2A, 2B, 2C and 3, some examples of the present application provide a semiconductor device 1000 comprising a first semiconductor structure 100. The first semiconductor structure 100 comprises a first select transistor 101, a second select transistor 102 and a capacitor structure 103. The first semiconductor structure 101 and the second select transistor 102 are connected with the capacitor structure 103 individually. The first select transistor 101 comprises a first channel layer 41, the second select transistor 102 comprises a gate 61, and the capacitor structure 103 comprises a first electrode layer 22. Two ends of the first electrode layer 22 are connected with the gate 61 of the second select transistor 102 and the first channel layer 41 of the first select transistor 101 respectively.

The first select transistor 101 is configured to be turned on or not turned on according to writing content and allows a writing voltage to flow into the capacitor structure 103 through the first select transistor 101; and the second select transistor 102 is configured to be turned on or not turned on according to storage content of the capacitor structure 103 and allows the storage content of the capacitor structure 103 to be read. To be specific, when a writing voltage is written, the first select transistor 101 is turned on, and the writing voltage flows into the capacitor structure 103 through the first select transistor 101 to realize a writing function. When the storage content of the capacitor structure 103 needs to be read, the second select transistor 102 is turned on to realize a reading function.

Referring to FIGS. 1A and 1B again, the positions of the first select transistor 101 and the second select transistor 102 may be changed and are not limited to the positions shown in FIG. 1A or 1B.

In the semiconductor device provided by the present application, by connecting the first select transistor 101 and the second select transistor 102 at two ends of the capacitor structure 103 respectively and making the two ends of the first electrode layer 22 of the capacitor structure 103 be connected with the first channel layer 41 of the first select transistor 101 and the gate 61 of the second select transistor 102 respectively, the first select transistor 101 and the second select transistor 102 perform a writing operation and a reading operation respectively. As such, the second select transistor 102 of the semiconductor device provided by the present application does not need a writing-back operation and a non-destructive reading operation can be achieved, which can effectively avoid the problem of state destruction caused by the reading operation.

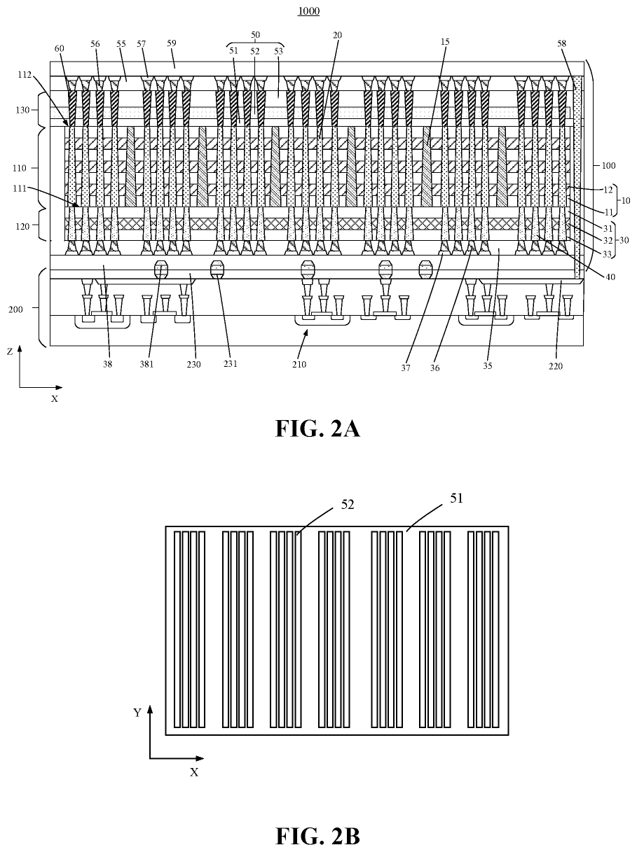

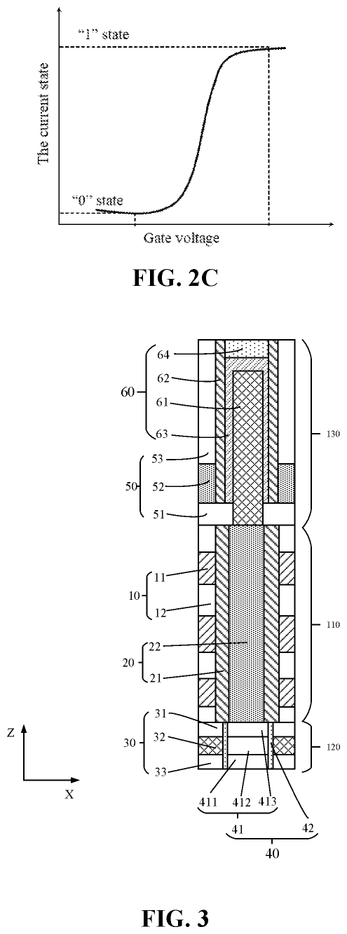

Referring to FIG. 2A again, the first semiconductor structure 100 further comprises a first stack structure 110, a second stack structure 120, and a third stack structure 130. The first stack structure 110 has a first side 111 and a second side 112 disposed oppositely in a first direction Z. and the capacitor structure 103 is located in the first stack structure 110. The second stack structure 120 is located on the first side 111 of the first stack structure 110, and the first select transistor 101 is located in the second stack structure 120. The third stack structure 130 is located on the second side 112 of the first stack structure 110, and the second select transistor 102 is located in the third stack structure 130.

In an example, the first stack structure 110 comprises at least one second electrode layer 11, a plurality of first insulation layers 12, and a plurality of first channel structures 20. Any second electrode layer 11 is located between two adjacent ones of the first insulation layers 12, and the first channel structures 20 are located in a deck formed by the second electrode layer 11 and the first insulation layers 12 along the first direction Z.

A composition material of the second electrode layer 11 comprises a conductive material, for example, monocrystalline silicon, polysilicon, doped monocrystalline silicon, doped polysilicon, tungsten, copper, aluminum, platinum, titanium, or ruthenium, etc. In this example, the composition material of the second electrode layer 11 comprises polysilicon.

A composition material of the first insulation layers 12 comprises an insulation material, such as silicon oxide, silicon nitride or silicon oxynitride, etc. In this example, the composition material of the first insulation layers 12 comprises silicon oxide.

In this example, the first stack structure 110 comprises a plurality of second electrode layers 11 and a plurality of first insulation layers 12, with the number of the first insulation layers 12 being one less than the number of the second electrode layers 11. In other examples, the first stack structure 110 may further comprise one second electrode layer 11 and two first insulation layers 12.

Each of the first channel structures 20 comprises a first electrode layer 22 extending in the first direction Z and an energy storage layer 21 extending in the first direction Z and located between the second electrode layer 11 and the first electrode layer 22. The second electrode layer 11 and the first insulation layer 12 are disposed around the energy storage layer 21, and the energy storage layer 21 is disposed around the first electrode layer 22. The capacitor structure 103 comprises the second electrode layer 11, the energy storage layer 21 and the first electrode layer 22.

In this example, a composition material of the energy storage layer 21 comprises: a ferroelectric material or an antiferroelectric material. The ferroelectric material has spontaneous polarization in two or more possible orientations at a finite temperature, and the orientations of the spontaneous polarization can be changed under an electric field. Ions inside lattices of the antiferroelectric material undergo similar spontaneous polarization to that of the ferroelectric material; but unlike the ferroelectric material, adjacent ones of the lattices inside the antiferroelectric material have the spontaneous polarization in opposite directions. For example, the composition material of the energy storage layer 21 may be selected from hafnium dioxide (HfO2), silicon-doped hafnium dioxide (Sia(HfO2) b), aluminum-doped hafnium dioxide (Ala(HfO2) b), zirconium-doped hafnium dioxide (Zra(HfO2) b), zirconium oxide (ZrO) and the like, where a and b are positive numbers. The energy storage layer 21 may be formed by a thin film deposition process, etc. In other examples, the material of the energy storage layer 21 is not limited to the ferroelectric material or the antiferroelectric material and may be set and adjusted according to actual needs.

A composition material of the first electrode layer 22 comprises a conductive material, for example, monocrystalline silicon, polysilicon, doped monocrystalline silicon, doped polysilicon, tungsten, copper, aluminum, platinum, titanium, or ruthenium, etc. In this example, the composition material of the second electrode layer 11 comprises tungsten. The first electrode layer 22 may be formed by the thin film deposition process, etc.

In this example, taking the plurality of first channel structures 20 as a group, the first stack structure 110 is divided into a plurality of channel structure groups.

An XYZ coordinate system is established using the first direction Z, a second direction X perpendicular to the first direction Z and a third direction Y perpendicular to the first direction Z and the second direction X. A stacking direction of the second electrode layer 11 and the first insulation layers 12 is the first direction Z.

The first stack structure 110 has a plurality of spacing structures 15 extending along the third direction Y and disposed as being spaced apart along the second direction X, to divide the first semiconductor structure 100 into a plurality of memory blocks disposed as being spaced apart, and each of the memory blocks comprises at least the first select transistor 101, the second select transistor 102 and the capacitor structure 103. One of the spacing structures 15 is located between two adjacent ones of the channel structure groups.

Each of the spacing structures 15 is used to space apart two adjacent ones of the channel structure groups, and comprises an insulation material, including at least one of silicon oxide, silicon oxynitride, ethoxysilane, low-temperature oxide, high-temperature oxide and silicon nitride, which is not limited by the present disclosure.

The second stack structure 120 comprises a second insulation layer 31, a word line 32, a third insulation layer 33 and second channel structures 40. The second insulation layer 31 is located on the first side 111 of the first stack structure 110, the word line 32 is located on a side of the second insulation layer 31 away from the first stack structure 110 and extends along the second direction X, the third insulation layer 33 is located on a side of the word line 32 away from the second insulation layer 31, and the second channel structures 40 extend along the first direction Z and are located within a deck formed by the second insulation layer 31, the word line 32 and the third insulation layer 33. The second channel structures 40 and the first channel structure 20 are disposed in one-to-one correspondence, and the first select transistor 101 comprises the second channel structures 40 and the word line 32. That is, orthographic projections of the second channel structures 40 on the first side 111 of the first stack structure 110 at least partially overlap the first channel structures 20.

Referring to FIG. 3 again, each of the second channel structures 40 comprises a first channel layer 41 and a first gate insulation layer 42. One end of the first channel layer 41 is connected with the first electrode layer 22, and the first gate insulation layer 42 is located between the word line 32 and the first channel layer 41. That is, the word line 32 surrounds each of the second channel structures 40. The second channel structures 40 cooperate with the word line 32 to constitute select transistors.

In an example, the first channel layer 41 comprises a first drain 411, a channel area 412 and a first source 413. The first drain 411 and the first source 413 are located on two opposite sides of the first channel area 412 in the first direction Z, and the first source 413 is connected with the first electrode layer 22. The word line 32 is disposed opposite to the first channel area 412, that is, the word line 32 faces the first channel area 412 from all directions. The second channel structures 40 cooperate with the word line 32 to constitute select transistors. The word line 32 controls the turn-on and turn-off of the select transistors. A control signal enters the select transistors from the word line 32 to control the turn-on and turn-off of the select transistors. The signal enters the first electrode layer 22 through the first source 413, and a voltage difference is generated between the first electrode layer 22 and the second electrode layer 11 to form an electric field.

Referring to FIGS. 2A and 3 again, the first semiconductor structure 100 further comprises first bit lines 37 which extend along the third direction Y and are located on a side of the second stack structure 120 away from the first stack structure 110. The first drain 411 of each of the second channel structures 40 is connected with one of the first bit lines 37. The first bit lines 37 are configured to write a saved state of a basic cell.

In an example, the first semiconductor structure 100 further comprises a sixth insulation layer 35 which is located on the side of the second stack structure 120 away from the first stack structure 110, and the first bit lines 37 are located in the sixth insulation layer 35. One of the first bit lines 37 is disposed opposite to and connected with one of the second channel structures 40. In an example, one of the first bit lines 37 is connected with the first source 413 through one first connector 36.

Referring to FIG. 2A, 2B and 3 again, the third stack structure 130 comprises at least a source line 52, a fourth insulation layer 53 and third channel structures 60. The source line 52 is located on the first side of the first stack structure 110 and extends along the second direction X. and the fourth insulation layer 53 is located on a side of the source line 52 away from the first stack structure 110. The third channel structures 60 extend along the first direction Z and are located in a deck formed by the source line 52 and the fourth insulation layer 53. The third channel structures 60 and the first channel structures 20 are disposed in one-to-one correspondence. That is, orthographic projections of the third channel structures 60 on the second side 112 of the first stack structure 110 at least partially overlap the first channel structures 20.

The third stack structure 130 further comprises a fifth insulation layer 51. The fifth insulation layer 51 is located on a side of the source line 52 close to the first stack structure 110, and the gate 61 is located within the source line 52, the fourth insulation layer 53 and the fifth insulation layer 51.

Each of the third channel structures 60 comprises a gate 61 connected with the first electrode layer 22, a second gate insulation layer 63, a second channel layer 62, and a second drain 64. The second gate insulation layer 63 clads the gate 61, the second channel layer 62 is disposed around the second gate insulation layer 63, and the second drain 64 is located on a side of the second gate insulation layer 63 away from the first electrode layer 22 and connected with the second channel layer 62. The source line 52 and the fourth insulation layer 53 are disposed around the second channel layer 62, and the second select transistor 102 comprises the source line 52 and the third channel structures 60.

The first semiconductor structure 100 further comprises second bit lines 57 that extend along the third direction X and are located on a side of the third stack structure 130 away from the first stack structure 110. The second drains 64 of the third channel structures 60 are connected with the second bit lines 57. The second bit lines 57 are configured to read a current state stored by the basic cell.

Referring to FIG. 2C again, the second select transistor 102 has different current states, namely a “0” state and a “1” state, according to its different gate voltages. When the gate voltage of the second select transistor 102 is low, the state read by the second bit lines 57 is the “0” state. When the gate voltage of the second select transistor 102 is high, the state read by the second bit lines 57 is the “1” state.

In an example, the first semiconductor structure 100 further comprises a seventh insulation layer 55 which is located on the side of the third stack structure 130 away from the first stack structure 110, and the second bit lines 57 are located in the seventh insulation layer 55. One of the second bit lines 57 is disposed opposite to and connected with one of the third channel structures 60. In an example, one of the second bit lines 57 is connected with one of the second drains 64 through one second connector 56.

In an example, the first semiconductor structure 100 further comprises a protective layer 59 that is located on a side of the second bit lines 57 away from the third channel structures 60 and covers the second bit lines 57 and the seventh insulation layer 55. The protective layer 59 is configured to protect the second bit lines 57.

In an example, the first semiconductor structure 100 further comprises a first bonding layer 38, and the first bonding layer 38 comprises a plurality of first bonding structures 381.

Referring to FIG. 2A again, the semiconductor device 1000 further comprises a second semiconductor structure 200. The second semiconductor structure 200 has a circuit element 210 for controlling the first semiconductor structure 100 and is located on a side of the first semiconductor structure 100, and the second semiconductor structure 200 is connected with the first semiconductor structure 100 in the first direction Z by bonding.

The circuit clement 210 may comprises at least one of a resistor, a capacitor, and a CMOS transistor, etc., or any combination thereof. In this example, the circuit element 210 comprises a CMOS transistor.

In an example, the second semiconductor structure 200 is located on the side of the second stack structure 120 away from the first stack structure 110 or on the side of the third stack structure 130 away from the first stack structure 110. In this example, the second semiconductor structure 200 is located on the side of the second stack structure 120 away from the first stack structure 110.

In an example, the second semiconductor structure 200 further comprises a second bonding layer 230 that comprises a plurality of second bonding structures 231 and is connected with the circuit element 210. The second bonding layer 230 is bonded with the first bonding layer 38, and the second bonding structures 231 are bonded with the first bonding structures 381. In some examples of the present application, the second bonding layer 230 is bonded with the first bonding structures 381 by covalent bonds, and the second bonding structures 231 are bonded with the first bonding structures 381 by metallic bonds. In other examples, the bonding between the second bonding layer 230 and the first bonding structures 381 is not limited to bonding by covalent bonds, and the bonding between the second bonding structures 231 and the first bonding structures 381 is not limited to bonding by metallic bonds.

In an example, the second semiconductor structure 200 further comprises an interconnection structure layer 220 that is located between the second bonding layer 230 and the circuit element 210 and is connected with the circuit element 210. The semiconductor device 1000 further comprises a connection portion 58 that is located on a side of the first semiconductor structure 100 and connected with the interconnection structure layer 220. One of the first select transistor 101 and the second select transistor 102 is connected with the interconnection structure layer 220 through the first bonding structures 381 and the second bonding structures 231, and the other one of the first select transistor 101 and the second select transistor 102 is connected with the connection portion 58.

Of course, in other examples of the present application, the semiconductor device 1000 may not comprise the second semiconductor structure 200.

In the semiconductor device 1000 provided by the present application, by connecting the first select transistor and the second select transistor to the capacitor structure and making the two ends of the first electrode layer of the capacitor structure be connected with the first channel layer of the first select transistor and the gate of the second select transistor respectively, the first select transistor and the second select transistor perform the writing operation and the reading operation respectively. As such, the second select transistor of the semiconductor device provided by the present application does not need the writing-back operation and the non-destructive read operation can be achieved, which can effectively avoid the problem of the state destruction caused by the reading operation.

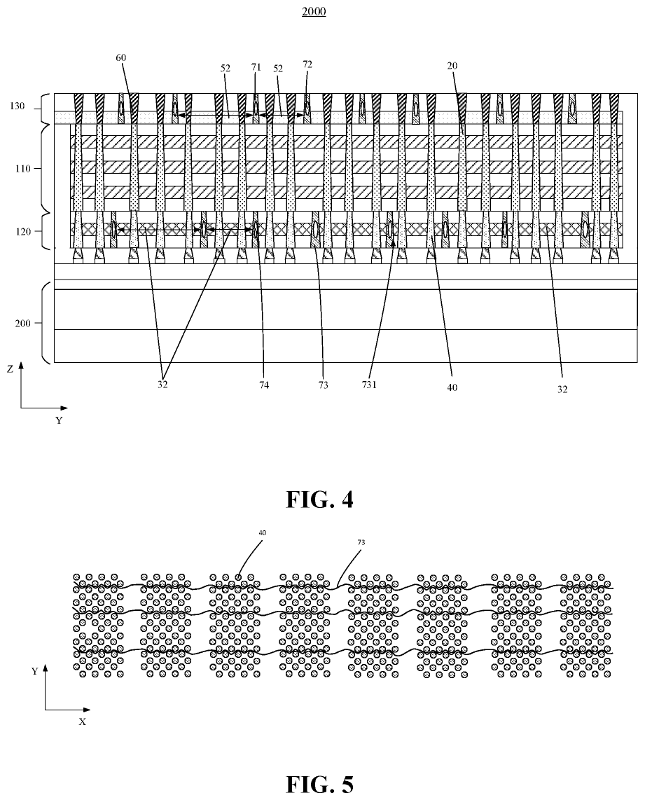

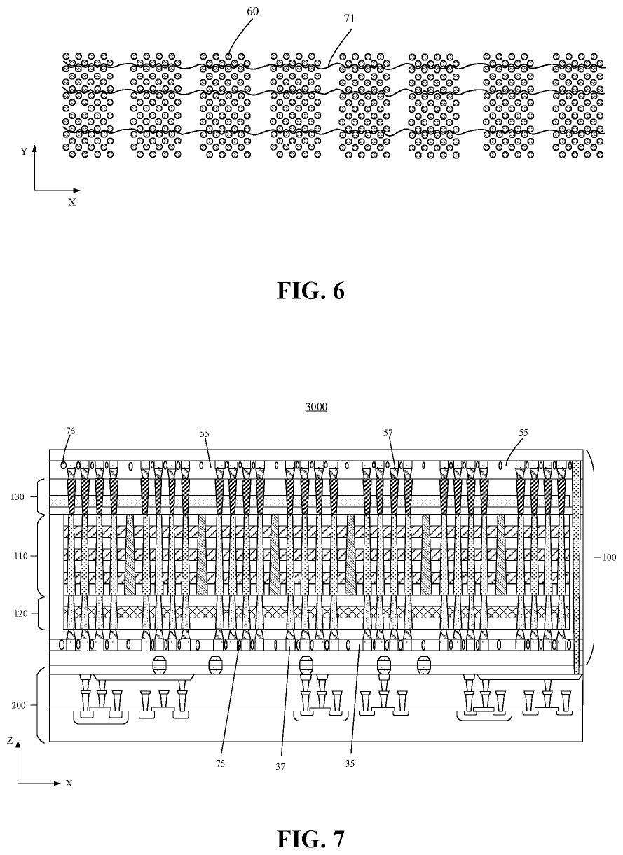

Referring to FIGS. 4 to 6, the present application further provides a semiconductor device 2000 which is similar in structure to the semiconductor device 1000, except that: the third stack structure 130 of the semiconductor device 2000 further comprises first spacers 71, and two adjacent ones of the source lines 52 are disposed as being spaced apart by one of the first spacers 71. Each of the first spacers 71 is located between two adjacent rows of the third channel structures 60 arranged along the second direction X and is S-shaped, and the first spacers 71 extend along the second direction X. The third stack structure 130 further comprises first air gaps 72 each located within each of the first spacers 71 and between at least part of two of the third channel structures 60 in two adjacent rows, and the first air gaps 72 extend within the first spacers 71 along the second direction X. The second stack structure 120 of the semiconductor device 2000 further comprises second spacers 73, and two adjacent ones of word lines 32 are disposed as being spaced apart by each of the second spacers 73. Each of the second spacers 73 is located between two adjacent rows of the second channel structures 40 arranged along the second direction X and is S-shaped, and the second spacers 73 extend along the second direction X. The second stack structure 120 further comprises second air gaps 74 each located within each of the second spacers 73 and between at least part of two of the second channel structures 40 in two adjacent rows, and the second air gaps 74 extend within the second spacers 73 along the second direction X.

Of course, the semiconductor device 2000 may also comprise at least one of the first air gaps 72 and the second air gaps 74.

There is air in the first air gaps 72 and the second air gaps 74. Air is an insulation dielectric with the lowest dielectric constant in the nature and has a dielectric constant of 1. Using the air gaps as a dielectric layer between adjacent ones of the second channel structures 40 can minimize the resistance-capacitance delay (RC delay) between the channel structures. Therefore, the second air gaps 74 can reduce coupling capacitance between the adjacent ones of the second channel structures 40, and the first air gaps 72 can reduce coupling capacitance between the adjacent ones of the third channel structures 60, thus meeting the requirement of the RC Delay after the size of the semiconductor device 2000 is reduced.

Referring to FIG. 7, the present application further provides a semiconductor device 3000 which is similar in structure to the semiconductor device 1000, except that: the second stack structure 120 of the semiconductor device 3000 further comprises third air gaps 75 each located within the sixth insulation layer 35 and between at least part of two adjacent ones of the first bit lines 37, and the third air gaps 75 extend along the third direction Y. The third stack structure 130 of the semiconductor device 3000 further comprises fourth air gaps 76 each located within the seventh insulation layer 55 and between at least part of two adjacent ones of the second bit lines 57, and the fourth air gaps 76 extend in the third direction Y.

Of course, the semiconductor device 3000 may also comprise at least one of the third air gaps 75 and the fourth air gaps 76.

There is air in the third air gaps 75 and the fourth air gaps 76. Air is an insulation dielectric with the lowest dielectric constant in the nature and has a dielectric constant of 1. Using the air gaps as a dielectric layer between the adjacent ones of the bit lines can minimize the RC delay between the bit lines. Therefore, the third air gaps 75 can reduce coupling capacitance between the adjacent ones of the first bit lines 37, and the fourth air gaps 76 can reduce coupling capacitance between the adjacent ones of the second bit lines 57, thus meeting the requirement of the RC delay after the size of the semiconductor device 3000 is reduced.

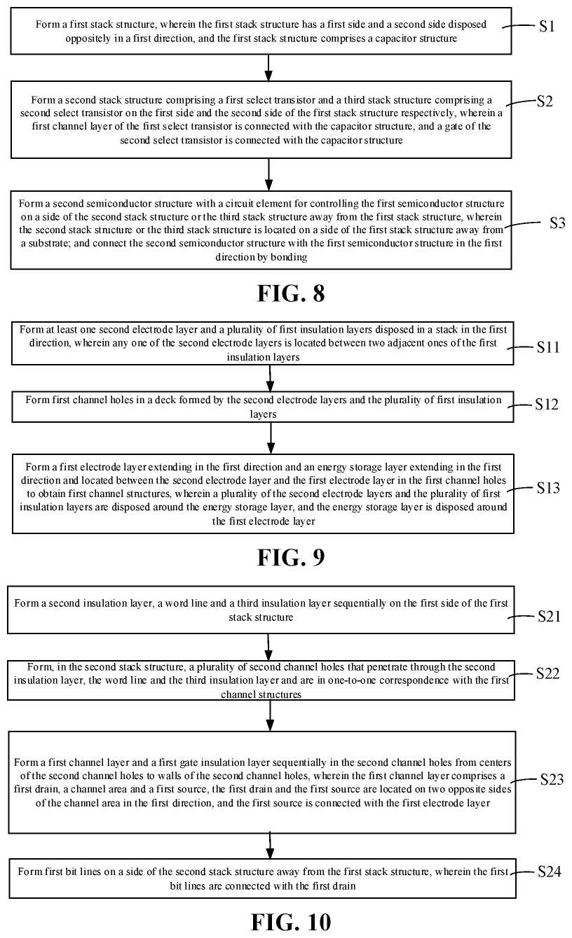

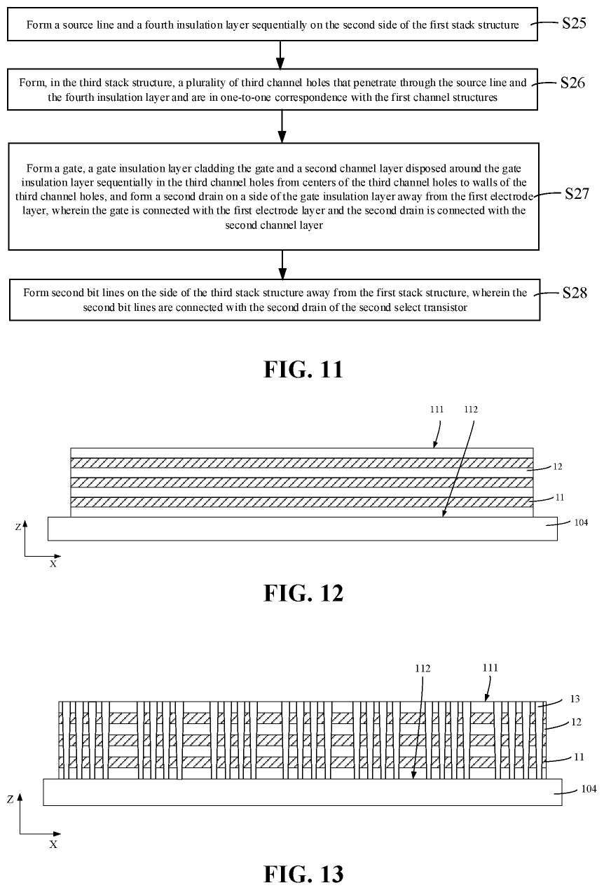

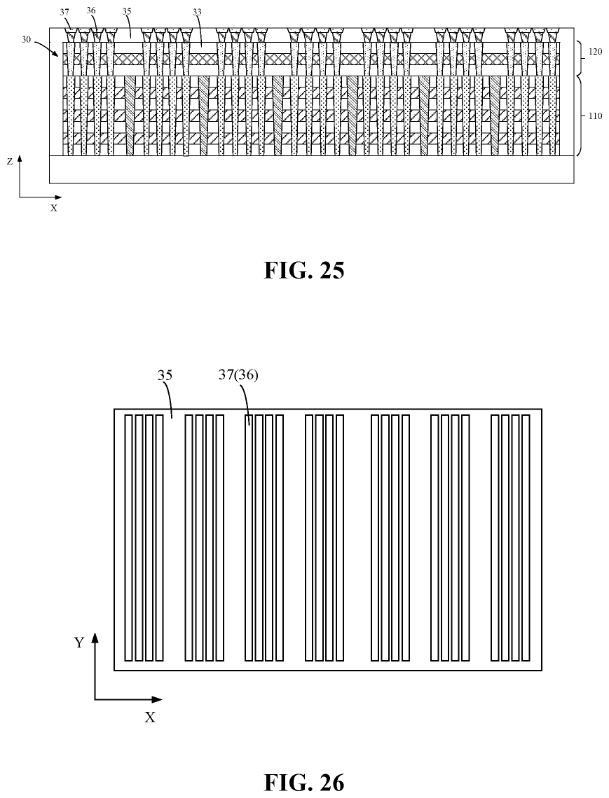

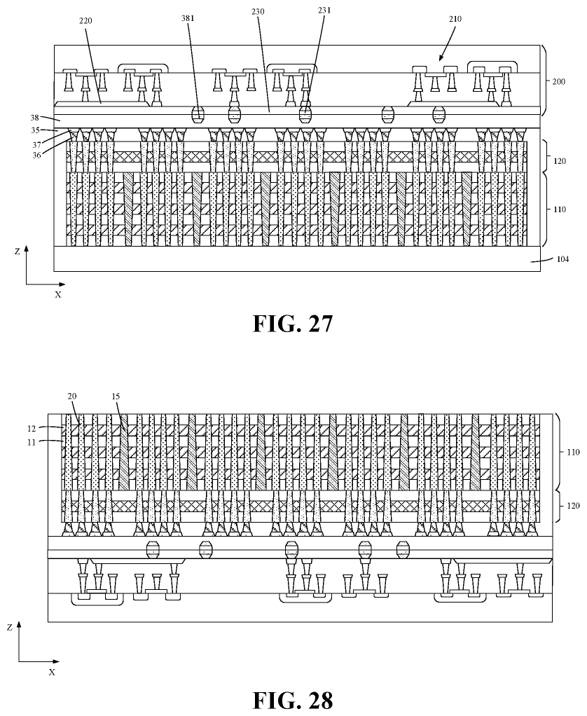

Referring to FIGS. 8 to 30, the present application further provides a fabrication method of a semiconductor device, which comprises:

S1: forming a first stack structure 110, wherein the first stack structure 110 has a first side 111 and a second side 112 disposed oppositely in a first direction Z, and the first stack structure 110 comprises a capacitor structure 103; and

S2: forming a second stack structure 120 comprising a first select transistor 101 and a third stack structure 130 comprising a second select transistor 102 on the first side 111 and the second side 112 of the first stack structure 110 respectively, wherein a first channel layer 41 of the first select transistor 101 is connected with the capacitor structure 103, and a gate 61 of the second select transistor 102 is connected with the capacitor structure 103.

A deck structure formed by the first stack structure 110, the second stack structure 120 and the third stack structure 130 is defined as a first semiconductor structure 100. The fabrication method of the semiconductor device further comprises S3: forming a second semiconductor structure 200 with a circuit element 210 for controlling the first semiconductor structure 100 on a side of the second stack structure 120 or the third stack structure 130 away from the first stack structure 110 and connecting the second semiconductor structure 200 with the first semiconductor structure 100 in the first direction Z by bonding.

In some examples of the present application, S3 is after S2.

In some examples of the present application, the second stack structure 120 and the third stack structure 130 in S2 are successively formed. After the formation of the second stack structure 120, S3 is performed to form the second semiconductor structure 200 on the side of the second stack structure 120 away from the first stack structure 110 and then form the third stack structure 130 on a side of the first stack structure 110 away from the second stack structure 120. Alternatively, after the formation of the third stack structure 130, S3 is performed to form the second semiconductor structure 200 on the side of the third stack structure 130 away from the first stack structure 110 and then form the second stack structure 120 on a side of the first stack structure 110 away from the third stack structure 130.

Referring to FIGS. 12 and 27 to 28, in some examples of the present application, prior to S1, the fabrication method further comprises: providing a substrate 104. Accordingly, S1 comprises: forming the first stack structure 110 on the substrate 104. One of the second stack structure 120 and the third stack structure 130 is located on a side of the first stack structure 110 away from the substrate 104. Prior to forming the other one of the second stack structure and the third stack structure, the fabrication method further comprises: removing the substrate 104. In an example, removing the substrate 104 comes before S3.

The substrate 104 may comprise monocrystalline silicon, polysilicon, monocrystalline germanium, a group III-V compound semiconductor material, a group II-VI compound semiconductor material, or other semiconductor materials.

Referring to FIGS. 9 and 12 to 15, S1 comprises:

S11: forming at least one second electrode layer 11 and a plurality of first insulation layers 12 disposed in a stack in the first direction Z, wherein any of the second electrode layers 11 is located between two adjacent ones of first insulation layers 12, referring to FIG. 12;

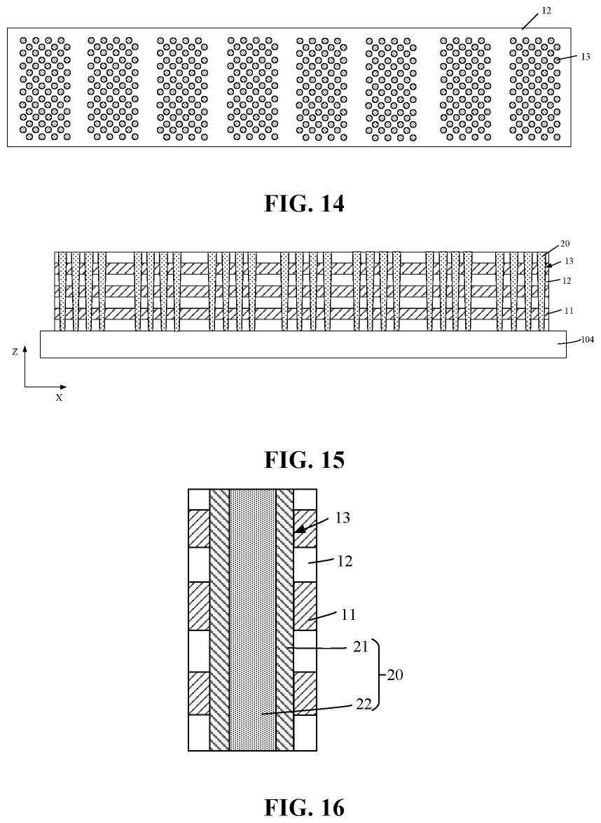

S12: forming first channel holes 13 in a deck formed by the second electrode layers 11 and the plurality of first insulation layers 12, referring to FIGS. 13 and 14; and

S13: forming a first electrode layer 22 extending in the first direction Z and an energy storage layer 21 extending in the first direction Z and located between the second electrode layer 11 and the first electrode layer 22 in the first channel holes 13 to obtain first channel structures 20, wherein a plurality of the second electrode layers 11 and the plurality of first insulation layers 12 are disposed around the energy storage layer 21, and the energy storage layer 21 is disposed around the first electrode layer 22, referring to FIGS. 15 and 16.

A composition material of the second electrode layers 11 comprises a conductive material, for example, monocrystalline silicon, polysilicon, doped monocrystalline silicon, doped polysilicon, tungsten, copper, aluminum, platinum, titanium, or ruthenium, etc. In this example, the composition material of the second electrode layers 11 comprises polysilicon.

A composition material of the first insulation layers 12 comprises an insulation material, such as silicon oxide, silicon nitride or silicon oxynitride, etc. In this example, the composition material of the first insulation layer 12 comprises silicon oxide.

In this example, a composition material of the energy storage layer 21 comprises: a ferroelectric material or an antiferroelectric material. The ferroelectric material has spontaneous polarization in two or more possible orientations at a finite temperature, and the orientations of the spontaneous polarization can be changed under an electric field. Ions inside lattices of the antiferroelectric material undergo similar spontaneous polarization to that of the ferroelectric material; but unlike the ferroelectric material, adjacent ones of the lattices inside the antiferroelectric material have the spontaneous polarization in opposite directions. For example, the composition material of the energy storage layer 21 may be selected from hafnium dioxide (HfO2), silicon-doped hafnium dioxide (Sia(HfO2)b), aluminum-doped hafnium dioxide (Ala(HfO2)b), zirconium-doped hafnium dioxide (Zra(HfO2)b), zirconium oxide (ZrO) and the like, where a and b are positive numbers. The energy storage layer 21 may be formed by a thin film deposition process, etc. In other examples, the material of the energy storage layer 21 is not limited to the ferroelectric material or the antiferroelectric material and may be set and adjusted according to actual needs.

A composition material of the first electrode layer 22 comprises a conductive material, for example, monocrystalline silicon, polysilicon, doped monocrystalline silicon, doped polysilicon, tungsten, copper, aluminum, platinum, titanium, or ruthenium, etc. In this example, the composition material of the second electrode layers 11 comprises tungsten. The first electrode layer 22 may be formed by the thin film deposition process, etc.

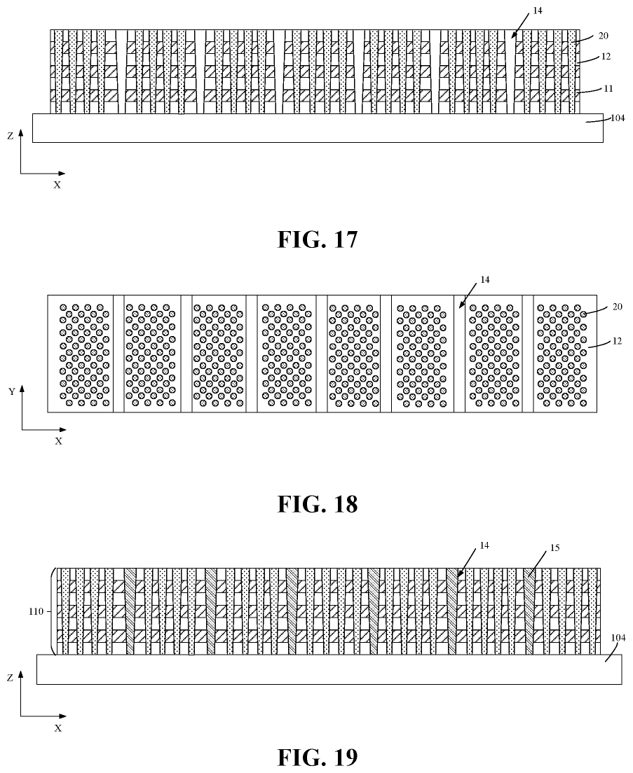

Referring to FIGS. 17 to 19, after S13, S1 further comprises: forming a plurality of spacing structure holes 14 extending along a third direction Y and disposed as being spaced apart along a second direction X in the second electrode layers 11 and the first insulation layers 12, and filling an insulation spacing material in the spacing structure holes 14 to form spacing structures 15 located in the second electrode layers 11 and the first insulation layers 12.

Referring to FIGS. 10 and 20 to 23, forming the second stack structure 120 comprising the first select transistor 101 on the first side 111 of the first stacked structure 110 in S2 comprises:

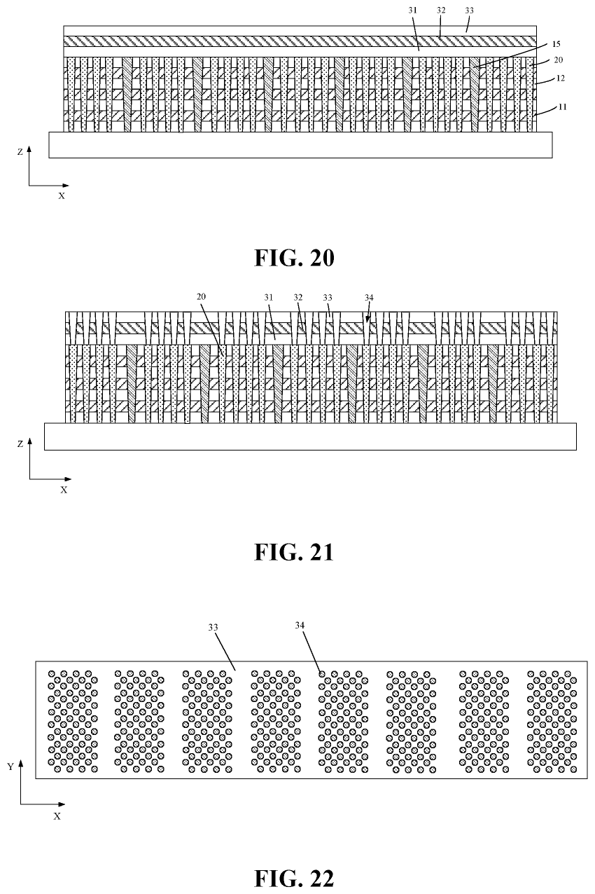

S21: forming a second insulation layer 31, a word line 32 and a third insulation layer 33 sequentially on the first side 111 of the first stack structure 110, referring to FIG. 20;

S22: forming, in the second stack structure 120, a plurality of second channel holes 34 that penetrate through the second insulation layer 31, the word line 32 and the third insulation layer 33 and are in one-to-one correspondence with the first channel structures 20, referring to FIGS. 21 and 22;

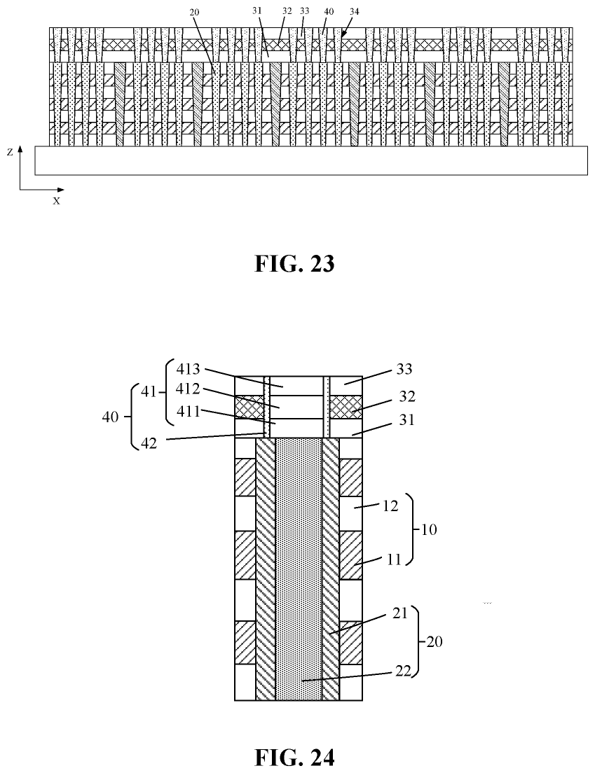

S23: forming a first channel layer 41 and a first gate insulation layer 42 sequentially in the second channel holes 34 from the centers of the second channel holes 34 to walls of the second channel holes 34, wherein the first channel layer 41 comprises a first drain 411, a channel area 412 and a first source 413, the first drain 411 and the first source 413 are located on two opposite sides of the channel area 412 in the first direction Z, and the first source 413 is connected with the first electrode layer 22, referring to FIGS. 23 and 24; and

S24: forming first bit lines 37 on a side of the second stack structure 120 away from the first stack structure 110, wherein the first bit lines 37 are connected with the first drain 411, referring to FIG. 25.

Referring to FIG. 4, in some examples of the present application, after S23, the fabrication method further comprises: forming second spacing holes 731 penetrating through the second stack structure 120 in the second stack structure 120, filling a spacing material in the second spacing holes 731 to obtain second spacers 73, and forming second air gaps 74 within the second spacers 73.

Referring to FIG. 5, S24 comprises: forming a sixth insulation layer 35 on the side of the second stack structure 120 away from the first stack structure 110 and forming the first bit lines 37 in the sixth insulation layer 35, wherein the first bit lines 37 are connected with the first drain 411.

Referring to FIG. 5, in some examples of the present application, after S24, the fabrication method further comprises: forming, in the sixth insulation layer 35, third air gaps 75 cach located between at least part of two adjacent ones of the first bit lines 37 and extending along the third direction Y.

Referring to FIGS. 11, 29 and 2A, forming the third stack structure 130 comprising the second select transistor 102 on the second side 112 of the first stack structure 110 in S2 comprises:

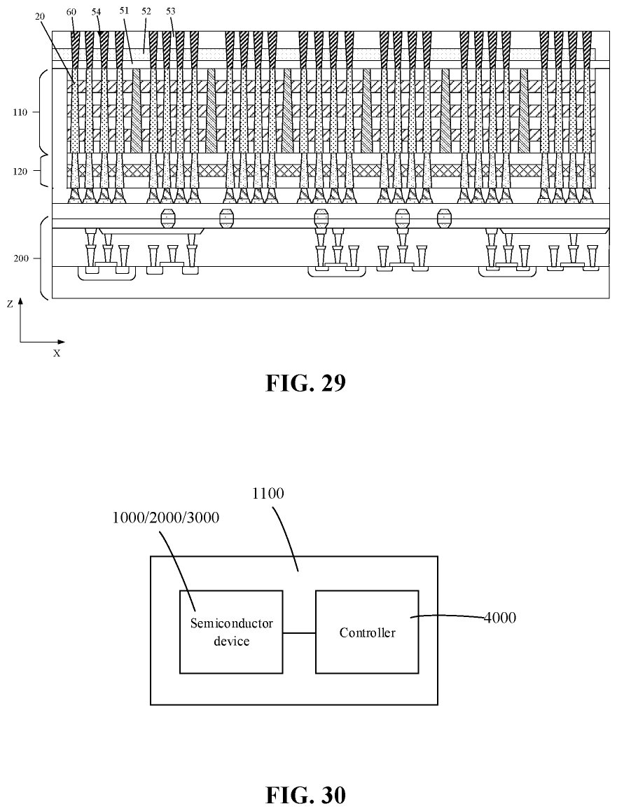

S25: forming a source line 52 and a fourth insulation layer 53 sequentially on the second side 112 of the first stack structure 110, referring to FIG. 29;

S26: forming, in the third stack structure 130, a plurality of third channel holes 54 that penetrate through the source line 52 and the fourth insulation layer 53 and are in one-to-one correspondence with the first channel structures 20, referring to FIG. 29;

S27: forming a gate 61, a second gate insulation layer 63 cladding the gate 61 and a second channel layer 62 disposed around the second gate insulation layer 63 sequentially in the third channel holes 54 from the centers of the third channel holes 54 to walls of the third channel holes 54, and forming a second drain 64 on a side of the second gate insulation layer 63 away from the first electrode layer 22, wherein the gate 61 is connected with the first electrode layer 22 and the second drain 64 is connected with the second channel layer 62, referring to FIGS. 29; and

S28: forming second bit lines 57 on the side of the third stack structure 130 away from the first stack structure 110, wherein the second bit lines 57 are connected with the second drain 64 of the second select transistor 102, referring to FIG. 2A.

Referring to FIG. 4, in some examples of the present application, after S27, the fabrication method further comprises: forming first spacing holes 711 penetrating through the third stack structure 130 in the third stack structure 130, filling a spacing material in the first spacing holes 711 to obtain first spacers 71, and forming first air gaps 72 in the first spacers 71.

Referring to FIG. 5, S28 comprises: forming a seventh insulation layer 55 on the side of the third stack structure 130 away from the first stack structure 110 and forming the second bit lines 57 in the seventh insulation layer 55, wherein each of the second bit lines 57 is connected with the second drain 64.

Referring to FIG. 5, in some examples of the present application, after S28, the fabrication method further comprises: forming, in the seventh insulation layer 55, fourth air gaps each located between at least part of two adjacent ones of the second bit lines 57 and extending in the third direction Y.

Referring to FIGS. 1A and 2A, in an example, the second semiconductor structure 200 further comprises an interconnection structure layer 220 that is located between a second bonding layer 230 and the circuit element 210 and is connected with the circuit element 210. After S28, the fabrication method further comprises: forming a connection portion 58 that is located on a side of the first semiconductor structure 100 and is connected with the interconnection structure layer 220, wherein one of the first select transistor 101 and the second select transistor 102 is connected with the interconnection structure layer 220 through the first bonding structure 381 and the second bonding structure 231, and the other one of the first select transistor 101 and the second select transistor 102 is connected with the connection portion 58.

Referring to FIG. 30, the present application further provides a memory system 1100 which comprises one or more semiconductor devices 1000/2000/3000 as described above, and a controller 4000. The controller 4000 is connected with the semiconductor devices 1000/2000/3000 and is configured to control the semiconductor devices 1000/2000/3000.

The memory system 1100 may be a mobile phone, a desktop computer, a laptop computer, a tablet computer, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatuses having memories therein. The controller may be configured to control operations of the semiconductor devices, such as reading, erasing, and programming operations.

In some examples, the controller is designed for operating in a low duty-cycle environment such as Secure Digital (SD) cards, Compact Flash (CF) cards, Universal Serial Bus (USB) flash drives, or other media for use in electronic apparatuses, such as personal computers, digital cameras, mobile phones, etc.

In some examples, the controller is designed for operating in high duty-cycle environment Solid-State Disks (SSDs) or Embedded Multi Media Cards (eMMCs) used as data memories for mobile apparatuses, such as smartphones, tablets, laptop computers, etc., and enterprise memory arrays.

According to the semiconductor device and the fabrication method thereof and the memory system provided by the present application, by connecting the first select transistor and the second select transistor to the capacitor structure and making the two ends of the first electrode layer of the capacitor structure be connected with the first channel layer of the first select transistor and the gate of the second select transistor respectively, the first select transistor and the second select transistor perform the writing operation and the reading operation respectively. As such, the second select transistor of the semiconductor device provided by the present application does not need the writing-back operation and the non-destructive reading operation can be achieved, which can effectively avoid the problem of the state destruction caused by the reading operation.

In addition, there is air in the first air gaps, the second air gaps, the third air gaps, and the fourth air gaps. Air is an insulation dielectric with the lowest dielectric constant in the nature and has a dielectric constant of 1. Using the air gaps as a dielectric layer between adjacent ones of the second channel structures or the third channel structures or the first bit lines or the second bit lines can minimize the RC delay between the adjacent channel structures or the adjacent bit lines.

In view of this, the present application provides a semiconductor device and a fabrication method thereof, and a memory system. The semiconductor device can realize non-destructive reading operation and does not need the writing-back operation any longer, so as to effectively avoid the problem of state destruction caused by the reading operation.

In order to solve the above problem, the technical solution provided by the present application is as follows:

The present application provides a semiconductor device, which comprises a first semiconductor structure comprising:
a first select transistor comprising a first channel layer;
a second select transistor comprising a gate; and
a capacitor structure comprising a first electrode layer, wherein two ends of the first electrode layer are connected with the gate of the second select transistor and the first channel layer of the first select transistor respectively.

In some examples of the present application, the first select transistor is configured to be turned on or not turned on according to writing content and allows a writing voltage to flow into the capacitor structure through the first select transistor; and the second select transistor is configured to be turned on or not turned on according to storage content of the capacitor structure and allows the storage content of the capacitor structure to be read.

In some examples of the present application, the first semiconductor structure further comprises:
a first stack structure having a first side and a second side disposed oppositely in a first direction, wherein the capacitor structure is located in the first stack structure;
a second stack structure located on the first side of the first stack structure, wherein the first select transistor is located in the second stack structure; and
a third stack structure located on the second side of the first stack structure, wherein the second select transistor is located in the third stack structure.

In some examples of the present application, the first stack structure comprises:
at least one second electrode layer;
a plurality of first insulation layers, wherein any one of the second electrode layers is located between two adjacent ones of the first insulation layers;
a plurality of first channel structures located in a deck formed by the second electrode layers and the first insulation layers along the first direction;
wherein each of the first channel structures comprises:
the first electrode layer extending in the first direction; and
an energy storage layer extending in the first direction and located between the second electrode layers and the first electrode layer,
wherein the second electrode layers and the first insulation layers are disposed around the energy storage layer, the energy storage layer is disposed around the first electrode layer, and the capacitor structure comprises the second electrode layers, the energy storage layer and the first electrode layer.

In some examples of the present application, the second stack structure comprises:
a second insulation layer located on the first side of the first stack structure;
a word line located on a side of the second insulation layer away from the first stack structure and extending along a second direction perpendicular to the first direction;
a third insulation layer located on a side of the word line away from the second insulation layer; and
second channel structures extending along the first direction and located in a deck formed by the second insulation layer, the word line and the third insulation layer,
wherein the second channel structures and the first channel structures are disposed in one-to-one correspondence, and the first select transistor comprises word line and one of the second channel structures.

In some examples of the present application, each of the second channel structures comprises:
the first channel layer with one end of the first channel layer being connected with the first electrode layer; and
a first gate insulation layer located between the word line and the first channel layer.

In some examples of the present application, the first channel layer comprises a first drain, a channel area and a first source, the first drain and the first source are located on two opposite sides of the channel area in the first direction, and the first source is connected with the first electrode layer.

In some examples of the present application, the first semiconductor structure further comprises first bit lines,

wherein the first bit lines extend along a third direction perpendicular to the first direction and intersecting the second direction and are located on a side of the second stack structure away from the first stack structure, and the first drain of each of the second channel structures is connected with the first bit lines.

In some examples of the present application, the third stack structure comprises:
at least a source line located on the first side of the first stack structure and extending along a second direction perpendicular to the first direction;
a fourth insulation layer located on a side of the source line away from the first stack structure; and
third channel structures extending along the first direction and located in a deck formed by the source line and the fourth insulation layer,
wherein the third channel structures and the first channel structures are disposed in one-to-one correspondence.

In some examples of the present application, the third stack structure further comprises a fifth insulation layer located on a side of the source line close to the first stack structure, and the gate is located within the source line, the fourth insulation layer and the fifth insulation layer.

In some examples of the present application, each of the third channel structures comprises:
the gate connected with the first electrode layer;
a second gate insulation layer cladding the gate;
a second channel layer disposed around the second gate insulation layer; and
a second drain located on a side of the second gate insulation layer away from the first electrode layer and connected with the second channel layer,
wherein the source line and the fourth insulation layer are disposed around the second channel layer, and the second select transistor comprises the source line and one of the third channel structures.

In some examples of the present application, the first semiconductor structure further comprises second bit lines,

wherein the second bit lines extend along a third direction perpendicular to the first direction and intersecting the second direction and are located on a side of the third stack structure away from the first stack structure, and the second drain of each of the third channel structures is connected with the second bit lines.

In some examples of the present application, two adjacent ones of the source lines are disposed as being spaced apart by a first spacer, the first spacer is located between two adjacent rows of the third channel structures arranged along the second direction and is S-shaped, the first spacer extends along the second direction, the third stack structure further comprises first air gaps each located in the first spacer and between at least part of two of the third channel structures in two adjacent rows, and each of the first air gaps extends within the first spacer along the second direction.

In some examples of the present application, two adjacent ones of the word lines are disposed as being spaced apart by a second spacer, the second spacer is located between two adjacent rows of the second channel structures arranged along the second direction and is S-shaped, the second spacer extends along the second direction, the second stack structure further comprises second air gaps cach located in the second spacer and between at least part of two of the second channel structures in two adjacent rows, and each of the second air gaps extends within the second spacer along the second direction.

In some examples of the present application, two adjacent ones of the first bit lines are disposed as being spaced apart, the second stack structure further comprises a sixth insulation layer, the first bit lines are located in the sixth insulation layer, the second stack structure further comprises third air gaps each located in the sixth insulation layer and between at least part of two adjacent ones of the first bit lines, and the third air gaps extend along the third direction.

In some examples of the present application, two adjacent ones of the second bit lines are disposed as being spaced apart, the third stack structure further comprises a seventh insulation layer, the second bit lines are located in the seventh insulation layer, and the third stack structure further comprises fourth air gaps each located in the seventh insulation layer and between at least part of two adjacent ones of the second bit lines, and the fourth air gaps extend along the third direction.

In some examples of the present application, the first stack structure has a plurality of spacing structures that extend along a third direction perpendicular to the first direction and intersecting the second direction and are disposed as being spaced apart along the second direction, so as to divide the first semiconductor structure into a plurality of memory blocks disposed as being spaced apart, and each of the memory blocks comprises at least the first select transistor, the second select transistor and the capacitor structure.

In some examples of the present application, the semiconductor device further comprises:
a second semiconductor structure that has a circuit clement for controlling the first semiconductor structure and is located on a side of the first semiconductor structure, wherein the second semiconductor structure is connected with the first semiconductor structure in the first direction by bonding.

In some examples of the present application, the second semiconductor structure is located on a side of the second stack structure away from the first stack structure or on a side of the third stack structure away from the first stack structure.

In some examples of the present application, the second semiconductor structure further comprises an interconnection structure layer located between the first semiconductor structure and the circuit element; and the semiconductor device further comprises a connection portion located on a side of the first semiconductor structure and connected with the interconnection structure layer, one of the first select transistor and the second select transistor is connected with the interconnection structure layer through a bonding structure, and the other one of the first select transistor and the second select transistor is connected with the connection portion.

The present application further provides a fabrication method of a semiconductor device, which comprises:
forming a first stack structure, wherein the first stack structure has a first side and a second side disposed oppositely in a first direction, and the first stack structure comprises a capacitor structure; and
forming a second stack structure comprising a first select transistor and a third stack structure comprising a second select transistor on the first side and the second side of the first stack structure respectively, wherein a first channel layer of the first select transistor is connected with the capacitor structure, and a gate of the second select transistor is connected with the capacitor structure.

In some examples of the present application, prior to forming the first stack structure, the fabrication method further comprises: providing a substrate;

forming the first stack structure comprises: forming the first stack structure on the first substrate,

wherein one of the second stack structure and the third stack structure is located on a side of the first stack structure away from the substrate; and prior to forming the other one of the second stack structure and the third stack structure, the fabrication method further comprises: removing the substrate.

In some examples of the present application, a deck structure formed by the first stack structure, the second stack structure and the third stack structure is defined as a first semiconductor structure; and

after forming one of the second stack structure and the third stack structure, the fabrication method further comprises:
forming a second semiconductor structure having a circuit element for controlling the first semiconductor structure on a side of the second stack structure or the third stack structure away from the first stack structure and connecting the second semiconductor structure with the first semiconductor structure in the first direction by bonding.

In some examples of the present application, forming the first stack structure comprises:
forming at least one second electrode layer and a plurality of first insulation layers disposed as being alternately stacked in the first direction;
forming first channel holes in a deck formed by the second electrode layers and the plurality of first insulation layers; and
forming, in the first channel holes, a first electrode layer extending in the first direction and an energy storage layer extending in the first direction and located between the second electrode layers and the first electrode layer, to obtain first channel structures, wherein a plurality of the second electrode layers and the plurality of first insulation layers are disposed around the energy storage layer, and the energy storage layer is disposed around the first electrode layer.

In some examples of the present application, forming the second stack structure comprising the first select transistor on the first side of the first stack structure comprises:
forming a second insulation layer, a word line and a third insulation layer sequentially on the first side of the first stack structure;
forming, in the second stack structure, a plurality of second channel holes that penetrate through the second insulation layer, the word line and the third insulation layer and are in one-to-one correspondence with the first channel structures; and
forming a first channel layer and a first gate insulation layer sequentially in the second channel holes from centers of the second channel holes to walls of the second channel holes, wherein the first channel layer comprises a first drain, a channel area and a first source, the first drain and the first source are located on two opposite sides of the channel area in the first direction, and the first source is connected with the first electrode layer.

In some examples of the present application, after forming the second stack structure comprising the first select transistor on the first side of the first stack structure, the fabrication method further comprises:
forming first bit lines on a side of the second stack structure away from the first stack structure, with the first bit lines being connected with the first drain.

In some examples of the present application, forming the first bit lines on the side of the second stack structure away from the first stack structure with the first bit lines being connected with the first drain comprises: forming a sixth insulation layer on the side of the second stack structure away from the first stack structure, and forming the first bit lines in the sixth insulation layer, with the first bit lines being connected with the first drain; and

after forming the first bit lines on the side of the second stack structure away from the first stack structure with the first bit lines being connected with the first drain, the fabrication method further comprises: forming, in the sixth insulation layer, third air gaps each located between at least part of two adjacent ones of the first bit lines and extending along a third direction.

In some examples of the present application, forming the third stack structure comprising the second select transistor on the second side of the first stack structure comprises:
forming a source line and a fourth insulation layer sequentially on the second side of the first stack structure;
forming, in the third stack structure, a plurality of third channel holes that penetrate through the source line and the fourth insulation layer and are in one-to-one correspondence with the first channel structures; and
forming the gate, a second gate insulation layer cladding the gate and a second channel layer disposed around the second gate insulation layer sequentially in the third channel holes from centers of the third channel holes to walls of the third channel holes, and forming a second drain on a side of the second gate insulation layer away from the first electrode layer, wherein the gate is connected with the first electrode layer and the second drain is connected with the second channel layer.

In some examples of the present application, after forming the third stack structure comprising the second select transistor on the second side of the first stack structure, the fabrication method further comprises:
forming second bit lines on a side of the third stack structure away from the first stack structure, with the second bit lines being connected with the second drain of the second select transistor.

In some examples of the present application, forming the second bit lines on the side of the third stack structure away from the first stack structure, with the second bit lines being connected with the second drain of the second select transistor comprises: forming a seventh insulation layer on the side of the third stack structure away from the first stack structure, and forming the second bit lines in the seventh insulation layer, wherein the second bit lines are connected with the second drain; and

after forming the second bit lines on the side of the third stack structure away from the first stack structure, with the second bit lines being connected with the second drain of the second select transistor, the fabrication method further comprises:
forming, in the seventh insulation layer, fourth air gaps each located between at least part of two adjacent ones of the second bit lines and extending in the third direction.

The present application further provides a memory system, comprising:
at least a semiconductor device as described above; and
a controller configured to control the semiconductor device.

According to the semiconductor device and the fabrication method thereof and the memory system provided by the present application, by connecting the first select transistor and the second select transistor to the capacitor structure and making the two ends of the first electrode layer of the capacitor structure be connected with the first channel layer of the first select transistor and the gate of the second select transistor respectively, the first select transistor and the second select transistor perform the writing operation and the reading operation respectively. As such, the second select transistor of the semiconductor device provided by the present application does not need the writing-back operation and the non-destructive reading operation can be achieved, which can effectively avoid the problem of the state destruction caused by the reading operation.

To sum up, the present application has been disclosed as above with examples, but the above examples are not used to limit the present application. Those of ordinary skill in the art may make various changes and modifications without departing from the spirits and scope of the present application. Therefore, the protection scope of the present application shall be defined by the claims.

What is claimed is:

1. A semiconductor device, comprising: a first semiconductor structure, wherein the first semiconductor structure comprises:
a first select transistor comprising a first channel layer;
a second select transistor comprising a gate; and
a capacitor structure comprising a first electrode layer, wherein two ends of the first electrode layer are connected with the gate of the second select transistor and the first channel layer of the first select transistor respectively.

2. The semiconductor device of claim 1, wherein the first select transistor is configured to be turned on or not turned on according to writing content and allows a writing voltage to flow into the capacitor structure through the first select transistor; and the second select transistor is configured to be turned on or not turned on according to storage content of the capacitor structure and allows the storage content of the capacitor structure to be read.

3. The semiconductor device of claim 1, wherein the first semiconductor structure further comprises:
a first stack structure having a first side and a second side disposed oppositely in a first direction, wherein the capacitor structure is located in the first stack structure;
a second stack structure located on the first side of the first stack structure, wherein the first select transistor is located in the second stack structure; and
a third stack structure located on the second side of the first stack structure, wherein the second select transistor is located in the third stack structure.

4. The semiconductor device of claim 3, wherein the first stack structure comprises:
a second electrode layer;
a plurality of first insulation layers, wherein any one of the second electrode layers is located between two adjacent ones of the first insulation layers;
a plurality of first channel structures located in a deck formed by the second electrode layers and the first insulation layers along the first direction;
wherein each of the first channel structures comprises:
the first electrode layer extending in the first direction; and
an energy storage layer extending in the first direction and located between the second electrode layers and the first electrode layer,
wherein the second electrode layers and the first insulation layers are disposed around the energy storage layer, the energy storage layer is disposed around the first electrode layer, and the capacitor structure comprises the second electrode layers, the energy storage layer and the first electrode layer.

5. The semiconductor device of claim 4, wherein the second stack structure comprises:
a second insulation layer located on the first side of the first stack structure;
a word line located on a side of the second insulation layer away from the first stack structure and extending along a second direction perpendicular to the first direction;
a third insulation layer located on a side of the word line away from the second insulation layer; and
second channel structures extending along the first direction and located in a deck formed by the second insulation layer, the word line and the third insulation layer,
wherein the second channel structures and the first channel structures are disposed in one-to-one correspondence, and the first select transistor comprises the word line and one of the second channel structures.

6. The semiconductor device of claim 5, wherein each of the second channel structures comprises:
the first channel layer with one end of the first channel layer being connected with the first electrode layer; and
a first gate insulation layer located between the word line and the first channel layer.

7. The semiconductor device of claim 6, wherein the first channel layer comprises a first drain, a channel area and a first source, the first drain and the first source are located on two opposite sides of the channel area in the first direction, and the first source is connected with the first electrode layer.

8. The semiconductor device of claim 7, wherein the first semiconductor structure further comprises first bit lines,
wherein the first bit lines extend along a third direction perpendicular to the first direction and intersecting the second direction and are located on a side of the second stack structure away from the first stack structure, and the first drain of each of the second channel structures is connected with the first bit lines.

9. The semiconductor device of claim 4, wherein the third stack structure comprises:
at least a source line located on the first side of the first stack structure and extending along a second direction perpendicular to the first direction;
a fourth insulation layer located on a side of the source line away from the first stack structure; and
third channel structures extending along the first direction and located in a deck formed by the source line and the fourth insulation layer,
wherein the third channel structures and the first channel structures are disposed in one-to-one correspondence.

10. The semiconductor device of claim 9, wherein each of the third channel structures comprises:
the gate connected with the first electrode layer;
a second gate insulation layer cladding the gate;
a second channel layer disposed around the second gate insulation layer; and
a second drain located on a side of the second gate insulation layer away from the first electrode layer and connected with the second channel layer,
wherein the source line and the fourth insulation layer are disposed around the second channel layer, and the second select transistor comprises the source line and one of the third channel structures.

11. The semiconductor device of claim 10, wherein the first semiconductor structure further comprises second bit lines,
wherein the second bit lines extend along a third direction perpendicular to the first direction and intersecting the second direction and are located on a side of the third stack structure away from the first stack structure, and the second drain of each of the third channel structures is connected with the second bit lines.

12. The semiconductor device of claim 9, wherein:
two adjacent ones of the source lines are disposed as being spaced apart by a first spacer, the first spacer is located between two adjacent rows of the third channel structures arranged along the second direction and is S-shaped, the first spacer extends along the second direction, the third stack structure further comprises first air gaps each located in the first spacer and between at least part of two of the third channel structures in two adjacent rows, and each of the first air gaps extends within the first spacer along the second direction; and
two adjacent ones of the word lines are disposed as being spaced apart by a second spacer, the second spacer is located between two adjacent rows of the second channel structures arranged along the second direction and is S-shaped, the second spacer extends along the second direction, the second stack structure further comprises second air gaps each located in the second spacer and between at least part of two of the second channel structures in two adjacent rows, and each of the second air gaps extends within the second spacer along the second direction.

13. The semiconductor device of claim 8, wherein:
two adjacent ones of the first bit lines are disposed as being spaced apart, the second stack structure further comprises a sixth insulation layer, the first bit lines are located in the sixth insulation layer, the second stack structure further comprises third air gaps each located in the sixth insulation layer and between at least part of two adjacent ones of the first bit lines, and the third air gaps extend along the third direction; and
two adjacent ones of the second bit lines are disposed as being spaced apart, the third stack structure further comprises a seventh insulation layer, the second bit lines are located in the seventh insulation layer, and the third stack structure further comprises fourth air gaps each located in the seventh insulation layer and between at least part of two adjacent ones of the second bit lines, and the fourth air gaps extend along the third direction.

14. The semiconductor device of claim 3, further comprising:
a second semiconductor structure that has a circuit element for controlling the first semiconductor structure and is located on a side of the first semiconductor structure, wherein the second semiconductor structure is connected with the first semiconductor structure in the first direction by bonding.

15. A fabrication method of a semiconductor device, comprising:
forming a first stack structure, wherein the first stack structure has a first side and a second side disposed oppositely in a first direction, and the first stack structure comprises a capacitor structure; and
forming a second stack structure comprising a first select transistor and a third stack structure comprising a second select transistor on the first side and the second side of the first stack structure respectively, wherein a first channel layer of the first select transistor is connected with the capacitor structure, and a gate of the second select transistor is connected with the capacitor structure.

16. The fabrication method of the semiconductor device of claim 15, wherein forming the first stack structure comprises:
forming a second electrode layer and a plurality of first insulation layers disposed as being alternately stacked in the first direction;
forming first channel holes in a deck formed by the second electrode layers and the plurality of first insulation layers; and
forming, in the first channel holes, a first electrode layer extending in the first direction and an energy storage layer extending in the first direction and located between the second electrode layers and the first electrode layer, to obtain first channel structures, wherein a plurality of the second electrode layers and the plurality of first insulation layers are disposed around the energy storage layer, and the energy storage layer is disposed around the first electrode layer.

17. The fabrication method of the semiconductor device of claim 16, wherein forming the second stack structure comprising the first select transistor on the first side of the first stack structure comprises:
forming a second insulation layer, a word line and a third insulation layer sequentially on the first side of the first stack structure;
forming, in the second stack structure, a plurality of second channel holes that penetrate through the second insulation layer, the word line and the third insulation layer and are in one-to-one correspondence with the first channel structures;
forming a first channel layer and a first gate insulation layer sequentially in the second channel holes from centers of the second channel holes to walls of the second channel holes, wherein the first channel layer comprises a first drain, a channel area and a first source, the first drain and the first source are located on two opposite sides of the channel area in the first direction, and the first source is connected with the first electrode layer; and
after forming the second stack structure comprising the first select transistor on the first side of the first stack structure, forming first bit lines on a side of the second stack structure away from the first stack structure, with the first bit lines being connected with the first drain.

18. The fabrication method of the semiconductor device of claim 17, wherein forming the first bit lines on the side of the second stack structure away from the first stack structure with the first bit lines being connected with the first drain comprises: forming a sixth insulation layer on the side of the second stack structure away from the first stack structure, and forming the first bit lines in the sixth insulation layer, with the first bit lines being connected with the first drain; and
after forming the first bit lines on the side of the second stack structure away from the first stack structure with the first bit lines being connected with the first drain, the fabrication method further comprises: forming, in the sixth insulation layer, third air gaps each located between at least part of two adjacent ones of the first bit lines and extending along a third direction.

19. The fabrication method of the semiconductor device of claim 16, wherein forming the third stack structure comprising the second select transistor on the second side of the first stack structure comprises:
forming a source line and a fourth insulation layer sequentially on the second side of the first stack structure;
forming, in the third stack structure, a plurality of third channel holes that penetrate through the source line and the fourth insulation layer and are in one-to-one correspondence with the first channel structures; and
forming the gate, a second gate insulation layer cladding the gate and a second channel layer disposed around the second gate insulation layer sequentially in the third channel holes from centers of the third channel holes to walls of the third channel holes, and forming a second drain on a side of the second gate insulation layer away from the first electrode layer, wherein the gate is connected with the first electrode layer and the second drain is connected with the second channel layer; and
after forming the third stack structure comprising the second select transistor on the second side of the first stack structure, forming second bit lines on a side of the third stack structure away from the first stack structure, with the second bit lines being connected with the second drain of the second select transistor.

20. A memory system, comprising:
at least a semiconductor device comprising a first semiconductor structure, wherein the first semiconductor structure comprises:
a first select transistor comprising a first channel layer;
a second select transistor comprising a gate; and
a capacitor structure comprising a first electrode layer, wherein two ends of the first electrode layer are connected with the gate of the second select transistor and the first channel layer of the first select transistor respectively, and
a controller configured to control the semiconductor device.
